(19) United States
(12) Patent Application Publication
(10) Pub. No.: US 2006/0161825 A1
(43) Pub. Date: Jul. 20, 2006

(54) Non-volatile memory device supporting high-parallelism test at wafer level

(75) Inventors: Guido Lomazzi, Castronno (IT); Ilaria Renna, Milano (IT); Marco Maccarone, Palestro (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignees: STMicroelectronics S.r.I., Agrate Brianza (IT); Hynix Semiconductor Inc., Ichon-si (KR)

(21) Appl. No.: 11/304,488

(22) Filed: Dec. 15, 2005

(30) Foreign Application Priority Data
Dec. 15, 2004 (EP) 04106609.3

(51) Int. Cl. G11C 29/00

(52) U.S. Cl. 714/718

(57) ABSTRACT

A non-volatile memory device includes a chip of semiconductor material. The chip includes a memory and control means for performing a programming operation, an erasing operation and a reading operation on the memory in response to corresponding external commands. The chip further includes testing means for performing at least one test process including the repetition of at least one of said operations by the control means, and a single access element for enabling the testing means.

### TECHNICAL FIELD

The present disclosure generally relates to the memory field. More specifically but not exclusively, the present disclosure relates to the testing of semiconductor memory devices.

### BACKGROUND INFORMATION

The test of semiconductor devices, and particularly of non-volatile memory devices is a very critical activity. The object of any test process is of verifying that each device under analysis operates correctly according to its specifications. This is of the utmost importance for ensuring a high level of quality of the corresponding production process.

A typical example is that of memory devices of the flash type with a NAND architecture, which must guarantee a very high reliability (such as 100K operation cycles and 10 years of data retention). However, due to technology reasons, there is a not negligible number of cells of the memory device that can work properly for a certain number of cycles before failing. The basic physical phenomenon occurring is that any read, program and erase operation internally generates very high voltages that cause a significant stress on oxide layers of the memory cells. Indeed, the thickness of the oxide layers is chosen in order to guarantee product reliability; however, due to many different production problems, it is possible that target oxide thickness is not reached. Particularly, oxide layers should be made thinner than expected, but not so thin to break up as soon as a significant electric field is applied. Therefore, the breaking of such thin oxide layers will happen after 100-1K erase-program cycles. This phenomenon is getting more and more evident and dangerous with the technology scaling.

In order to detect the memory devices with thinner oxide layers (also called “early failing devices”), it is not possible to apply voltages higher than the ones usually needed for standard operations. In fact, such high voltages might damage good oxide layers as well; moreover, their generation would involve a significant waste of area of a silicon chip wherein the memory device is integrated.

A method to reduce the time required to perform the test process is of testing the memory device under stress conditions; a typical example is the so-called burn-in test, which accelerates the break up of thinner oxide layers by having the electronic devices work for certain number of cycles at very high or very low temperature (simulating a long period of operation at room temperature).

In any case, the time required to perform the test process is very long. This drawback is particular acute in modern memory devices with high density; for example, it is possible to have memory devices of the NAND flash type with a capacity up to 4 Gbit. Particularly, let us consider a memory device of 2 Gbit, which is partitioned into 2K sectors that can be erased individually (typically in 2 ms). Each sector comprises 64 pages each one of 2 k bytes, which can be read/programmed individually; typically, each programming operation requires 300 μs, plus the data insertion time (50 ns every 1 byte). Supposing to execute 1K erase-program cycles, it results that the total test process time is given by the following formulas:
erase time: 2 ms*2K sectors*1Kcycles=4Ks˜68 minutes;
program time: (64 pages*2K sectors*1Kcycles)*(300 μs+(50 ns*2K))=51,2Ks˜14 hours.

A solution known in the art for reducing the time required by the test process is of executing parallel program/erase operations (that is, programming more than one page or erasing more than one sector simultaneously). However, the charge pump circuits that generate the high voltages necessary to execute the program operation have to be over-dimensioned, in such a way to support the higher load due to the parallel operations. Moreover, it is necessary to provide the memory device with additional logic circuits in order to manage the parallel erase/program operations. This cases an excessive waste of area on the chip.

A further solution is to execute a parallel testing (that is, testing more than one memory device at the same time) directly at the wafer level (before packaging). To execute such a parallel test, it is necessary to develop a suitable probe-card (a device that permits to contact the pads of each memory chip with corresponding probes). The main drawback of this solution is that each memory device normally has a number of pads equal to 15-16, so that a probe-card with a very high number of probes is required. However, this strongly increases the cost of the probe-card.

Another solution comprises simplifying the operations of the test process. However, the test process time is not significantly reduced. Moreover, in this case it is not possible to recreate the conditions that can cause the early failing of the memory devices exactly.

Built-in Self Testing (BIST) techniques are also known in the art. The BIST is a technique that has become increasingly popular in the last years, especially for testing complex semiconductor devices. For this purpose, the semiconductor device is provided with internal structures permitting the controllability and the observability of each pin and/or internal sequential element. A drawback of this solution is that it requires additional integrated structures (wasting area on the chip).

In any case, a common problem in the test process sphere is that a user may activate (accidentally or not) the test process when the memory device is in operation.

### BRIEF SUMMARY OF THE INVENTION

An embodiment of the present invention proposes a solution for the implementation of memory devices suitable to be tested with a high parallelism.

Particularly, an aspect of the present invention provides a non-volatile memory device including a chip of semiconductor material. The chip includes a memory and control means for performing a programming operation, an erasing operation and a reading operation on the memory in response to corresponding external commands. The chip further includes testing means for performing at least one test process including the repetition of one or more of said operations by the control means, and a single access element for enabling the testing means.

In this way, the test process is performed using the circuitry already available in the memory device.

An advantage of the proposed structure is that the test process can be performed in a short time with a high degree of parallelism, and without wasting silicon area in the chip.

Another advantage of the proposed structure is that the test process can be performed by means of a highly parallel and cost-effective probe card.

The embodiments of the invention described in the following provide additional advantages.

For example, the testing means is disabled and enabled in response to the application of a first and a second voltage to the access element.

This implementation is very simple but as the time effective.

In one embodiment, the access element is not operatively accessible from the outside when the chip is embedded in a package.

In this case, the test process cannot be inadvertently started.

Advantageously, the memory chip includes a further access element for providing indications about the completion of the test process.

This allows controlling the test process in a very simple manner.

In one embodiment, the number of repetitions of the above-mentioned operations is selected in response to a first signal.

The proposed feature adds flexibility to the test process.

Advantageously, the memory chip includes means for setting the number of repetitions according to the length of a sequence of toggling of the first signal.

This implementation is very simple.

In one embodiment, the memory chip further includes means for selecting one of the test processes in response to a second signal.

The proposed feature adds further flexibility to the test process.

Advantageously, the selection of the test processes is done according to the frequency of toggling of the second signal.

The proposed implementation is very simple.

Another aspect of the present invention provides a corresponding process for producing a non-volatile memory device.

Without detracting from its general applicability the test process is performed at wafer level.

In a specific embodiment of the invention, the test process lasts for a period corresponding to the application of a predetermined voltage to the access element.

This implementation is very simple, but at the same time effective.

### BRIEF DESCRIPTION OF THE SEVERAL VIEWS OF THE DRAWINGS

The features of embodiments of the invention, as well as further features and advantages, will be best understood by reference to the following detailed description, given purely by way of a non restrictive indication, to be read in conjunction with the accompanying drawings. In this respect, it is expressly intended that the figures are not necessary drawn to scale and that, unless otherwise indicated, they are merely intended to conceptually illustrate the structures and procedures described herein. Particularly:

FIG. 1 illustrates a simple and schematic diagram of a memory device in which the solution according to an embodiment of the invention is applicable;

FIG. 2 shows a functional diagram of an embodiment of a memory chip included in the memory device;

FIGS. 3a-3c show a flow chart relating to an illustrative implementation of a test process according to an embodiment of the invention;

FIG. 4 illustrates a wafer of semiconductor material which memory chips are tested using a probe-card according to an embodiment of the invention; and

FIG. 5 shows a flow chart relating to an illustrative implementation of a simplified test process according to another embodiment of the invention.

### DETAILED DESCRIPTION

In the following description, numerous specific details are given to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

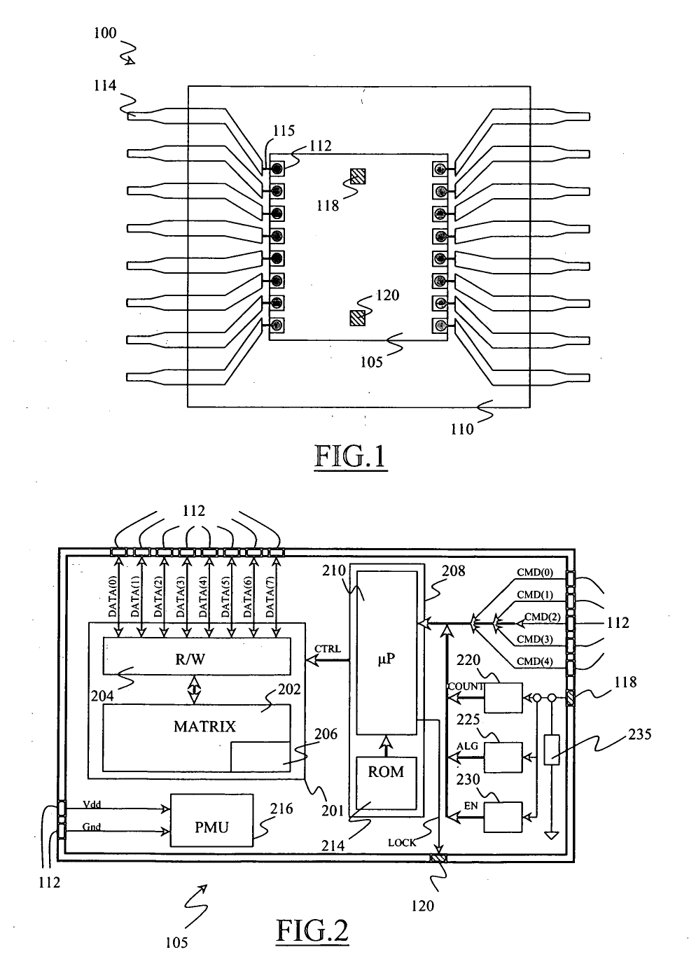

With references to the drawings, FIG. 1 is a simplified and generic diagram of a non-volatile memory device 100 that includes a memory chip 105. The memory chip 105 may be embedded in a package 110 whose function is to protect the memory chip 105, to insulate it from the noise coming from other electronic devices, to evacuate heat generated during its functioning, and so on, as it is well known in the art. The memory chip 105 comprises a plurality of metalized emplacements (pads) 112. The pads 112 are connected to a corresponding plurality of terminals 114; for this purpose, each pad 112 is bonded with a corresponding terminal 114 by means of a wire 115, generally formed by aluminum or gold. The terminals 114 allow the memory chip 105 to receive input signals and power supply voltages from and to provide output signals to the outside of the memory device 100. Two extra pads 118 and 120 are used to control a test process of the memory chip 105 before its packaging (as will be more clear in the following); the extra pads 118 and 120 are not bonded with any terminal 114.

Turning now to FIG. 2, a functional representation of the memory chip 105 is illustrated. Particularly, the core of the memory chip 105 comprises a block 201. Such memory block 201 includes a matrix 202 of memory cells for storing information (typically partitioned into sectors); in the example at issue, the memory cells of the matrix 202 are arranged according to a NAND architecture. The matrix 202 is connected to a read/write circuit 204, whose purpose is to select the addressed memory cells and to perform the desired operations on them (i.e., reading, writing or erasing). The read/write circuit 204 is connected to a control bus CTRL that provides corresponding signals CTRL necessary to command it properly (for convenience, in this document the signals and the corresponding physical lines are denoted with the same references). Eight bi-directional data lines DATA(0), . . . ,DATA(7) are connected to the read/write circuit 204 in such a way to establish a link between the memory block 201 and the outside. The corresponding data signals DATA(0), . . . ,DATA(7) can represent values to be stored in or read from the matrix 202, or addresses of selected memory cells of the matrix 202. An extra-area 206 of the matrix 202 is dedicated to store a number of test cycles to be performed during the test process of the memory chip 105.

The control bus CTRL originates from a control block 208, which comprises a microprocessor 210 connected to a ROM 214. The purpose of the microprocessor 210 is to drive the memory block 201 correctly by means of the control signals CTRL. The control signals CTRL are generated according to instructions stored in the ROM 214, which instructions are executed in response to command signals CMD(0), . . . ,CMD(4); these command signals are provided by five unidirectional command lines CMD(0), . . . ,CMD(4) grouped in a bus coming from the outside.

A power management unit PMU 216 receives two reference voltages (for example, a power supply voltage Vdd, and a ground voltage Gnd) from the outside through corresponding lines. The PMU 216 generates and distributes the correct power supply voltages to every circuital block of the memory chip 105.

The data lines DATA(0), . . . ,DATA(7), the command lines CMD(0), . . . ,CMD(4), and the two lines providing the voltage Vdd and the ground voltage are connected with the outside of the memory chip 105 by means of the pads 112 (bonded with corresponding terminals).

The microprocessor 210 receives commands (by means of the command lines CMD(0), . . . ,CMD(4)) not only from the outside, but even from three further circuital blocks: a counter block 220, an algorithm selecting block 225 and a test enabling block 230. Particularly, the counter block 220 provides a counter signal COUNT (indicative of the number of test cycles to be executed), the algorithm selecting block 225 provides a select signal ALG (indicative of the test algorithm to be executed), and the test enabling block 230 provides an enabling signal EN (for starting the test process). Each of the blocks 220, 225 and 230 is connected to the extra pad 118 for receiving a corresponding signal from the outside.

The extra pad 118 is also connected to the ground line via a bleeder 235. The purpose of the bleeder 235 is to establish a low-resistance conductivity path toward the ground line, so as to avoid leaving the extra pad 118 floating. Finally, the other extra pad 120 is connected to a line coming from the control block 208 and carrying a signal LOCK (indicative of a completion of the test process).

The memory chip 105 can operate in two modes, and precisely: in a “burn-in mode”, in which the memory chip 105 is subjected to the test process, and in a “standard mode”, in which the memory chip 105 is used for storing information as usual. The operative mode of the memory chip 105 is selected according to the voltage applied to the extra pad 118; particularly, the memory chip 105 is in the burn-in mode or in the standard mode when the extra pad 118 is at the voltage Vdd or at the ground voltage, respectively. When the memory chip 105 is packaged, the memory chip 105 will be always in the standard mode. Indeed, the extra pad 118 is maintained at the ground voltage by the bleeder 235. In this condition, the extra pad 118 cannot be directly driven from the outside, since it is not bonded with any terminal. In this respect, it should be noted that the extra pad 118 actually has a connection with the outside (by means of the bleeder 235 that is connected to a terminal providing the ground voltage). However, the extra pad 118 cannot be driven to a voltage different from the reference one, and then it cannot be switched into the burn-in mode. Therefore, the extra pad 118 can be deemed not operatively accessible from the outside.

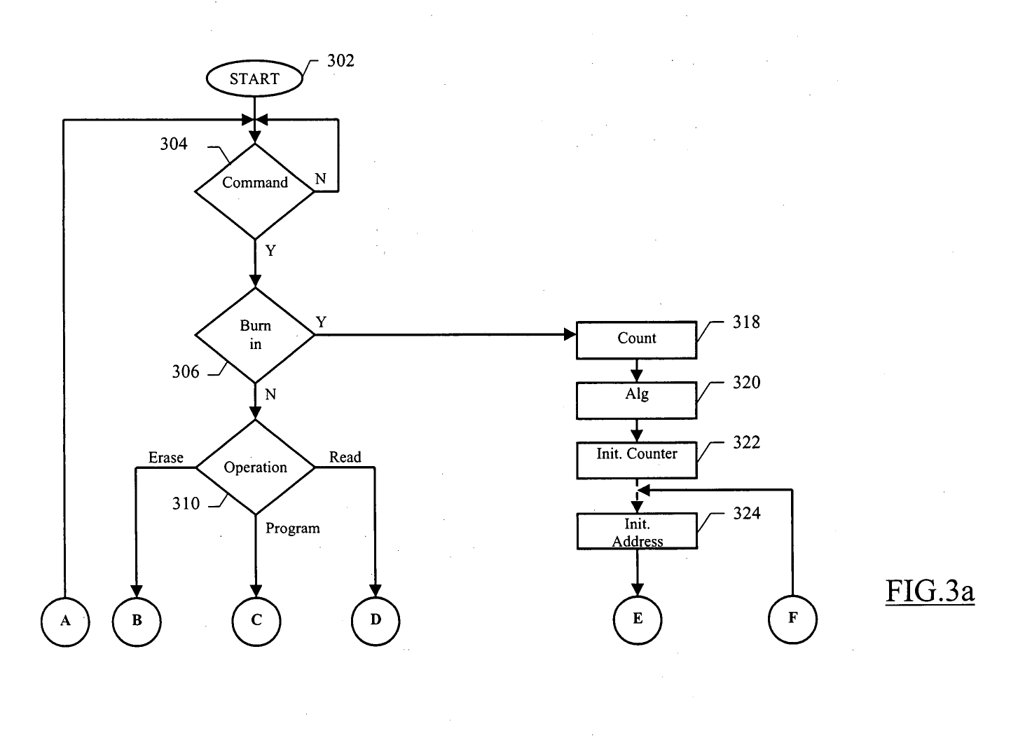

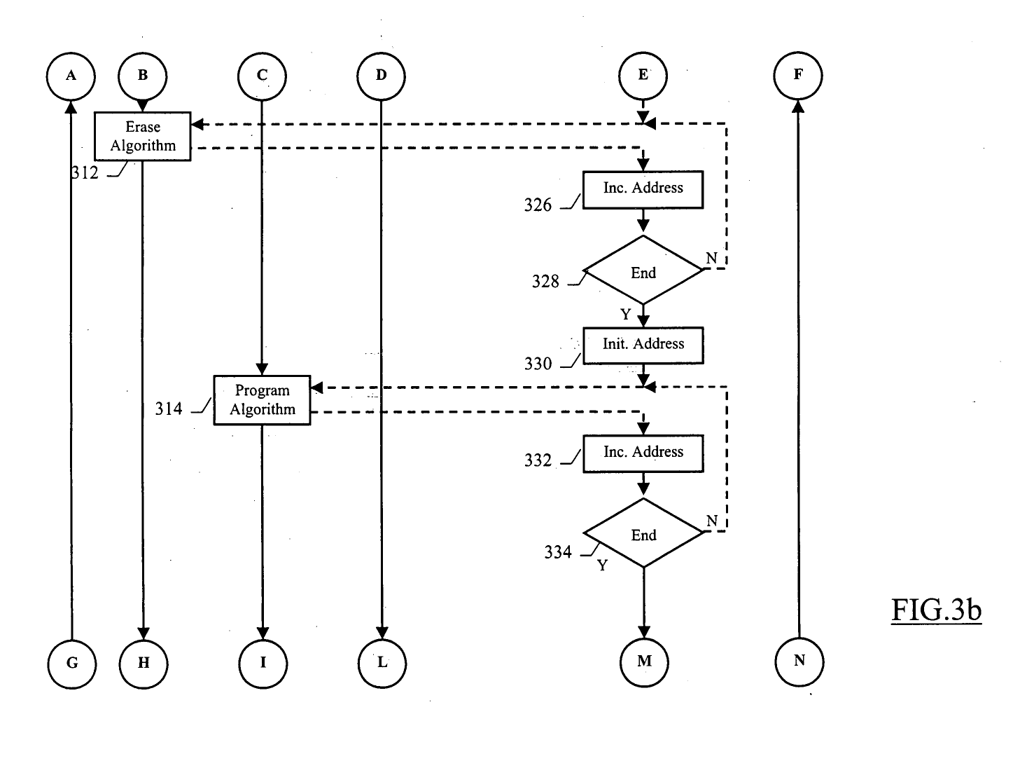

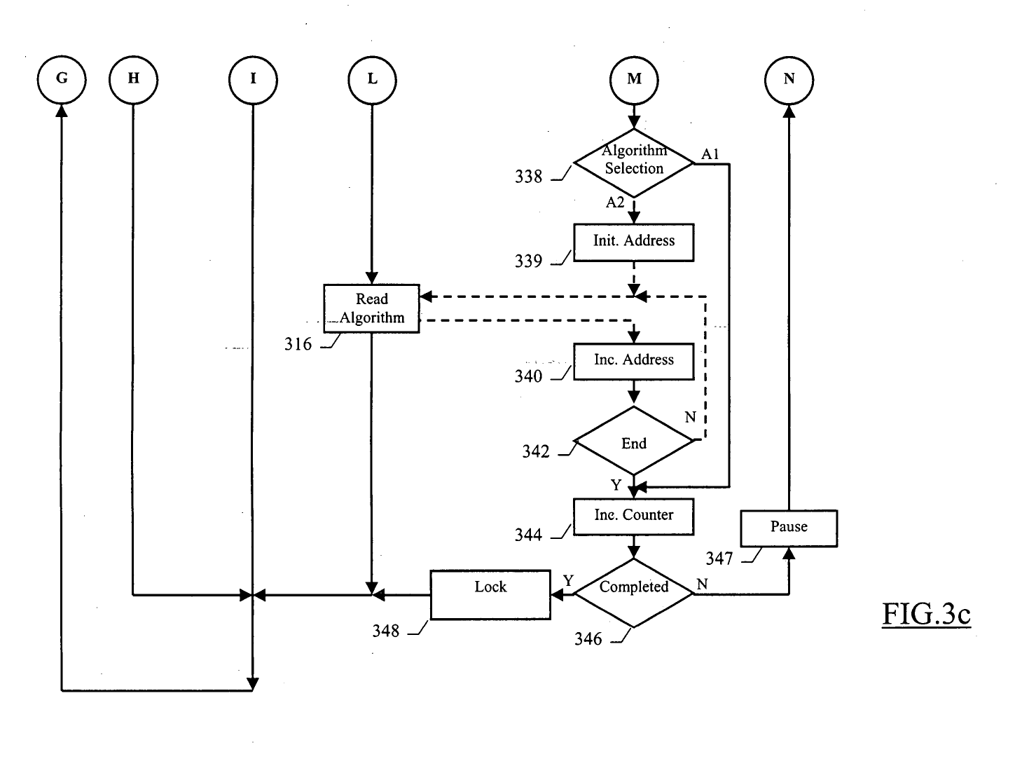

Referring to FIGS. 3a-3c, a flow chart 300 relating to an example implementation of a functioning method of the memory device (according to an embodiment of the invention) is illustrated. The flow of activity begins at the start block 302, and then enters a waiting cycle 304. As soon as any command is received from the outside, the flow of activity proceeds to a decisional block 306. If the memory device is in the standard mode (e.g., corresponding extra pad at the ground voltage and then enabling signal EN deasserted), the method branches at the further decisional block 310 according to the received command signals CMD(0), . . . ,CMD(4). Particularly, depending on the command signals CMD(0), . . . ,CMD(4), the flow of activity continues to an erase algorithm block 312, to a program algorithm block 314, or to a read algorithm block 316.

If the flow of activity enters the erase algorithm block 312, the microprocessor drives the memory block to perform an erasing operation on a selected sector of the matrix by means of the control signals CTRL. The selection of the sector to be erased is determined by an address received from the outside by means of the data lines DATA(0), . . . ,DATA(7) and interpreted by the read/write circuit 204.

On the other hand, if the flow of activity enters the program algorithm block 314, the microprocessor drives the memory block to perform a programming operation on a selected group of memory cells of the matrix (i.e., a page) by means of the control signals CTRL. The address of the selected page and the data to be stored therein is likewise received from the outside by means of the data lines DATA(0), . . . ,DATA(7) and interpreted by the read/write circuit.

Finally, if the flow of activity enters the read algorithm block 316, the microprocessor drives the memory block to perform a reading operation on a selected page of the matrix by means of the control signals CTRL. The address of the selected page is received from the outside by means of the data lines DATA(0), . . . ,DATA(7) and interpreted by the read/write circuit; the read values are then returned to the outside by means of the same data lines DATA(0), . . . ,DATA(7).

Once the erase algorithm 312, the program algorithm 314, or the read algorithm 316 is completed, the flow of activity returns to the waiting cycle 304.

Referring back to the block 306, the memory device enters the burn-in mode in response to the application of the voltage Vdd to the extra pad (signal EN asserted). As a result, the flow of activity proceeds to the block 318; in this phase, a series of pulses of amplitude equal to the voltage Vdd is applied from the outside to the extra pad. The counter block determines the number of test cycles that will be performed during the test process accordingly; the counter block is structured in such a way to detect the end of the series of voltage pulses when no more voltage pulse is received after a certain period of time. For example, if the counter block receives n voltage pulses, it means that the test process must include the repetition of 2ⁿ test cycles. The counter block then provides the signal COUNT (indicating the number of test cycles 2ⁿ) to the microprocessor through the command lines CMD(0), . . . ,CMD(4). In response thereto, the microprocessor stores the value representing the number of test cycles 2ⁿ into the corresponding extra-area of the matrix.

The flow of activity now proceeds to block 320, wherein another series of pulses of amplitude equal to the voltage Vdd (and with a predetermined duration) is applied from the outside to the extra pad. The algorithm selection block determines the desired algorithm that will be performed during the test process according to the frequency of the voltage pulses. For example, the algorithm selecting block chooses a first algorithm (A1) or a second algorithm (A2) when the frequency is lower or higher, respectively, than a threshold value; as described in detail in the following, each test cycle involves the erase-program or the erase-program-read of the whole memory matrix in the first algorithm A1 and in the second algorithm A2, respectively. The algorithm selection block then provides the signal ALG (indicating the selected algorithm) to the microprocessor through the command lines CMD(0), . . . ,CMD(4).

Considering now block 322, the microprocessor initializes to zero a value m stored in a counter register (which indicates a current cycle of the test process in progress). Successively, the flow of activity proceeds to block 324, wherein an address register included in the microprocessor (indicating a current address of the matrix) is likewise reset to zero.

The flow of activity then returns to the erase algorithm block 312, wherein the microprocessor drives the memory block to perform the above-described erasing operation on a sector of the matrix; in this case, however, the address of the sector to be erased is forced by the microprocessor according to the content of its address register (pointing to the first sector at the beginning). Continuing to block 326, the value stored in the address register is incremented in such a way to point to a next sector of the matrix. A test is now made at block 328 to verify whether all the sectors of the matrix have been erased (that is, the value stored in the address register points to a last sector of the matrix, depending on its size). If not, the flow of activity returns to the erase algorithm block 312 to perform the erasing operation of the next sector.

Conversely, the method descends into the block 330, wherein the address register is reset again to zero. The flow of activity then returns to the program algorithm block 314, wherein the microprocessor drives the memory block to perform the above-described program operation on a page of the matrix. Even in this case, the address of the page to be programmed is forced by the microprocessor according to the content of its address register (pointing to the first page at the beginning); moreover, the microprocessor also forces predefined values to be stored in the selected page (for example, all 1). Continuing to block 332, the value stored in the address register is incremented in such a way to point to a next page of the matrix. A test is now made at block 334 to verify whether all the pages of the matrix have been programmed (that is, the value stored in the address register points to a last page of the matrix). If not, the flow of activity returns to the program algorithm block 314 to perform the programming operation of the next page.

The flow of activity now branches at block 338 according to the selected test process. Particularly, if the second algorithm (A2=erase-program-read) has been selected the address register is reset again to zero at block 339. The flow of activity then returns to the read algorithm block 316, wherein the microprocessor drives the memory block to perform the above-described read operation on a page of the matrix. Even in this case, the address of the page to be read is forced by the microprocessor according to the content of its address register (pointing to the first page at the beginning); moreover, the microprocessor intercepts the read values (so as to verify their correctness). Continuing to block 340, the value stored in the address register is incremented in such a way to point to a next page of the matrix. A test is now made at block 342 to verify whether all the pages of the matrix have been read. If not, the flow of activity returns to the read algorithm block 316 to perform the read operation of the next page.

Conversely, the test cycle is completed and the method descends into block 344. The same point is also reached from block 338 directly if the first algorithm (A1=erase-program) has been selected. In this phase, the microprocessor increments the counter register storing the current number of test cycles m. A test is now made at block 346 to determine whether the number of test cycles m already performed is equal to the value 2ⁿ stored in the extra-area of the matrix. If not, the flow of activity proceeds to the block 347, in which a pause is execute in such a way to permit at the circuital blocks of the memory device to conclude the operations engaged during the test cycle. Then, the flow of activity returns to block 324 for reiterating the test cycle.

Referring back to block 346, if the test process is completed the microprocessor 210 asserts the signal LOCK by bringing the corresponding extra-pad 120 to the voltage Vdd; this allows communicating that the test process has been completed to the outside. The memory chip then returns to the standby mode at the waiting cycle 304.

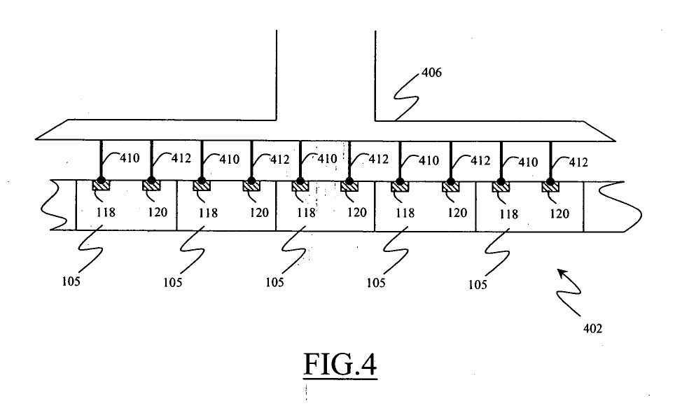

According to the proposed structure and algorithm, the test process can be operated directly at wafer level with a high parallelism, as showed in FIG. 4. Referring to this Figure, a wafer of semiconductor material 402, including a plurality of memory chips 105, is illustrated during a burn-in test process. For this purpose, the wafer 402 is placed onto a chunk (not shown in the figure); a probe card 406 is then used to drive each memory chip 105 included in the wafer 402 in such a way to perform the burn-in test process. The probe card 406 includes two probes 410, 412 for each memory chip 105 (in addition to a probe for providing the ground voltage and a probe for providing the voltage Vdd, not shown in the Figure).

The purpose of the probe 410 is to contact the extra-pad 118, so as to provide the voltage corresponding to the enabling signal EN, to the counter signal COUNT, and the select signal ALG. Naturally, as the extra pad 118 is connected to a terminal providing the ground voltage via the corresponding bleeder, the probe 410 must have a high driving capability so as to force the desired voltage. The purpose of the probe 412 is instead to contact the extra-pad 120, so as to receive the signal LOCK indicating when the test process has been completed. It has to be noted that the extra-pad 120 of each memory chip 105 must have a pull-up capability stronger than the sum of all the pull-down capabilities of the others memory chips 105 on the wafer 402; otherwise, the probe card 406 would not be able to detect the completion of the test process on the corresponding memory chip 105.

Consequently, it is possible to perform the burn-in test process by using only two probes 410, 412 per memory chip 105. As a result, the probe card 406 can be strongly simplified (for the same number of memory chips 105); vice versa, the burn-in test process can be performed on a higher number of memory chips 105 simultaneously (for the same complexity of the probe card 406).

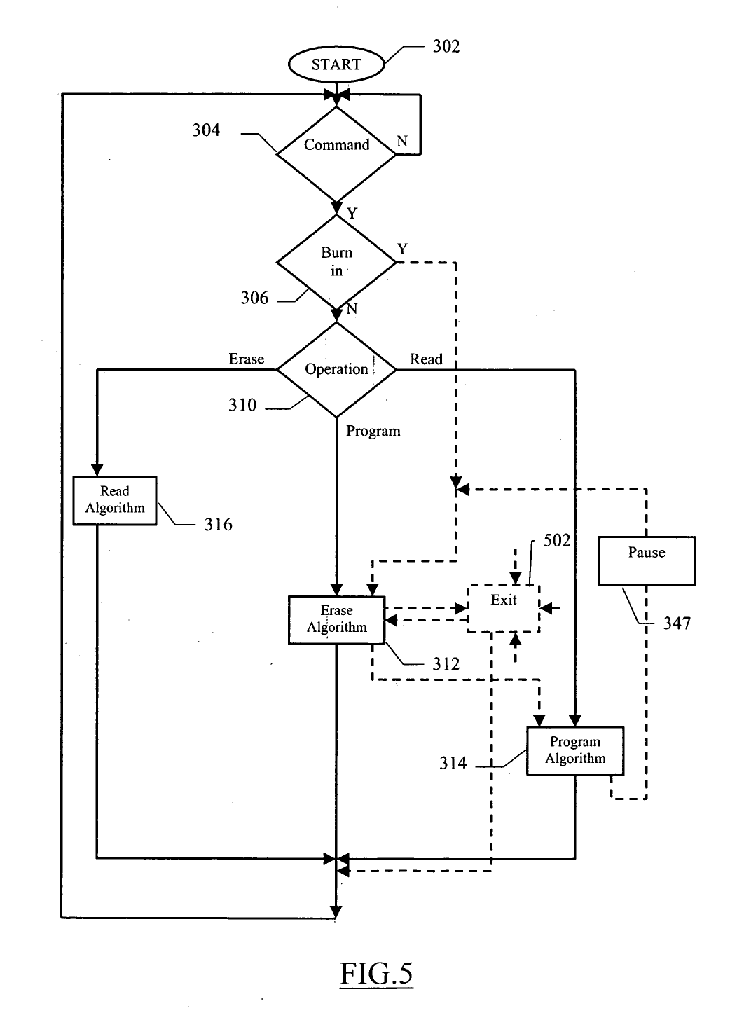

According to another embodiment of the present invention, in FIG. 5 an implementation of a simpler functioning method of the memory device is illustrated (the elements corresponding to the ones shown in FIGS. 3a-3c are denoted with the same references, and their explanation is omitted for the sake of brevity). This method requires that the memory chip includes only one extra-pad. In this case, when the flow of activity arrives at the block 306, the memory device enters into the burn-in mode in response to the application of the voltage Vdd to the extra pad, and remains in this mode until the extra pad is turned back to the ground voltage (that is, until the probe card supplies the voltage Vdd to it). Each test cycle is now composed by an erase operation and a program operation only. As soon as the extra-pad is returned to the ground voltage, the test process ends and the flow of activity exits the cycle by proceeding to the block 502. Before exiting the test process, the method returns to the erase algorithm block 312, thus performing a further erase operation (so as to leave the memory cells always erased).

It has to be noted that the number of repetitions of the test cycle is now determined by the time of application of the voltage Vdd to the extra-pad; this time can be calculated with a certain degree of accuracy once known the average time necessary to perform an erase operation followed by a program operation.

This simpler method does not permit to set the number of repetitions of the test cycle precisely. However, it necessitates a single extra-pad only, thereby allowing using a far simpler probe card (having only one probe per memory chip). Consequently, the burn-in test process can be performed on a higher number of memory chips simultaneously.

Naturally, in order to satisfy local and specific requirements, a person skilled in the art may apply to the solution described above many modifications and alterations. Particularly, although the present invention has been described with a certain degree of particularity with reference to various embodiment(s) thereof, it should be understood that various omissions, substitutions and changes in the form and details as well as other embodiments are possible; moreover, it is expressly intended that specific elements and/or method steps described in connection with any disclosed embodiment of the invention may be incorporated in any other embodiment as a general matter of design choice.

For example, even though in the preceding description reference has been made to a burn-in test of a memory device of the flash type with a NAND architecture, this is not to be intended as a limitation; indeed, the same concepts may also be applied to any other test process and/or any other non-volatile memory device.

Likewise, the extra pad can be replaced by any other access element (such as a photo detector).

It is not excluded that the test process could be enabled/disabled in response to different voltages.

Moreover, other packages are contemplated (for example, of the flip-chip type).

In addition, the completion of the test process can be communicated with an equivalent signal.

Likewise, the selection of the number of test cycles to be performed and/or the selection of the test algorithm to be used can be made by different interpretations of the toggling of corresponding signals, or by the application of different signals.

It is contemplated that different test algorithms can be chosen (for example, involving erase-read-program-read cycles), or the simultaneous erasure of all the sectors.

Moreover, it will be apparent to those skilled in the art that the additional features providing further advantages are not essential for carrying out the embodiments, and may be omitted or replaced with different features.

For example, the test process can be enabled/disabled with different signals.

Similar considerations apply if the chip is put on the market being not embedded in any package (for example, as a Known Good Die, or KGD); in this case, the extra-pad(s) are not listed among the pads to be bonded. However, the use of the proposed solution for naked-chip applications is not excluded.

As another example, the solution of one embodiment can be implemented even without the possibility of choosing the number of test cycles to be performed.

In any case, the use of the proposed solution at the level of single memory chips (already diced) is contemplated (even if far less advantageous).

As another example, in the case in which the number of repetitions of the test cycle is determined by the time of application of the predetermined voltage to the extra-pad, the solution can be implemented even without performing the further erase operation but terminating the test process immediately (even if it implies a worst control).

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention and can be made without deviating from the spirit and scope of the invention.

These and other modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A non-volatile memory device including a chip of semiconductor material, the chip including a memory and control means for performing a programming operation, an erasing operation and a reading operation on the memory in response to corresponding external commands, the chip further including testing means for performing at least one test process including repetition of at least one of said operations by the control means, and a single access element for enabling the testing means.

2. The non-volatile memory device of claim 1 wherein the testing means is disabled in response to an application of a first voltage to an access element and is enabled in response to an application of a second voltage to the access element.

3. The non-volatile memory device of claim 2 wherein the memory device further includes a package embedding the chip, the access element being not operatively accessible from outside the package for enabling the testing means.

4. The non-volatile memory device of claim 3 wherein the chip includes a further access element for providing an indication of completion of the test process.

5. The non-volatile memory device of claim from 1 wherein each test process includes a predefined number of repetitions of the at least one operation, the chip further including means for storing the predefined number, means for measuring a current number of repetitions, and means for terminating the test process when the current number reaches the predefined number.

6. The non-volatile memory device of claim 5 wherein the chip further includes means for setting the predefined number according to a first signal applied to an access element.

7. The non-volatile memory device of claim 6 wherein the means for setting includes means for determining the predefined number according to a length of a sequence of toggling of the first signal.

8. The non-volatile memory device of claim 6 wherein the at least one test process comprises a plurality of different test processes, the chip further including means for selecting one of the test processes in response to a second signal applied to the access element.

9. The non-volatile memory device of claim 8 wherein the means for selecting includes means for determining the selected test process according to a frequency of a further sequence of toggling of the second signal.

10. A process for producing a non-volatile memory device, the process comprising:
providing a chip of semiconductor material, the chip including a memory and control element to perform a programming operation, an erasing operation and a reading operation on the memory in response to corresponding external commands; and
enabling testing of the chip using a single access element to perform at least one test process, including repetition of at least one of said operations by the control element.

11. The process of claim 10, further including:
embedding the chip into a package, the access element being not operatively accessible from outside the package for enabling the testing.

12. The process of claim 10, further including:
providing a wafer of semiconductor material including a plurality of chips, the at least one test process being performed on each chip of the wafer; and
dicing the chips.

13. The process of claim 10, further including:
applying a predetermined voltage to the access element for enabling the testing; and
removing the predetermined voltage for disabling the testing after a predetermined period.

14. An apparatus, comprising:
a semiconductor chip having a memory and a first structure operatively coupled to the memory to perform a programming operation, an erasing operation, and a reading operation on the memory in response to at least one command;
a second structure operatively coupled to the first structure to perform at least one test operation, including repetition of at least one of the operations performed by the first structure; and
an access element coupled to the second structure to enable the second structure to perform the test operation.

15. The apparatus of claim 14 wherein the memory comprises a NAND memory device.

16. The apparatus of claim 14 wherein the second structure can be enabled in response to application of a first signal to the access element and can be disabled in response to application of a second signal to the access element.

17. The apparatus of claim 14, further comprising a package that embeds the semiconductor chip, wherein the access element is operatively inaccessible from outside the package to enable the second structure.

18. The apparatus of claim 14 wherein each test operation includes a number of repetitions of the at least one operation, the apparatus further comprising:
a storage area to store the number of repetitions;
a first element included with the second structure to measure a current number of repetitions; and
a third element, included with the second structure, operatively coupled to the storage area and the first element to terminate the test operation if the current number reaches the stored number.

19. The apparatus of claim 18 wherein the second structure further includes:
a setting element, coupled to the access element, to set the number to be stored in the storage area according to a length of a sequence of toggling of a first input signal applied to the access element; and
a selection element, coupled to the access element, to select one test operation from a plurality of different test operations according to a frequency of toggling of a second input signal applied to the access element.

20. A method for a semiconductor device having chip with a memory and a control structure, the method comprising:
providing an external command to the control structure to perform a programming operation, an erasing operation, or a reading operation on the memory;
testing the chip by performing at least one test process, including repetition of at least one of the programming, erasing, and reading operations by the control structure; and
enabling the testing using an access element.

21. The method of claim 20 wherein the chip is embedded in a package, the method further comprising restricting access to the access element from outside the package to prevent enabling of the testing.

22. The method of claim 20 wherein each test process includes a number of repetitions of the operations by the control structure, the method further comprising:
storing the number of repetitions;
determining a current number of repetitions; and
terminating the test process if the determined current number reaches the stored number.

23. The method of claim 22, further comprising:
setting the number to be stored according to a length of a sequence of toggling of a first input signal applied to the access element; and
selecting one test process from a plurality of different test processes according to a frequency of toggling of a second input signal applied to the access element.
